(19) United States
(12) Patent Application Publication
(10) Pub. No.: US 2019/0246521 A1
(43) Pub. Date: Aug. 8, 2019

(54) HEAT CONDUCTIVE SHEET, METHOD OF PRODUCING HEAT CONDUCTIVE SHEET, AND SEMICONDUCTOR DEVICE

(71) Applicant: Dexerials Corporation, Shinagawa-ku Tokyo (JP)

(72) Inventors: Tatsuo KUMURA, Shinagawa-ku, Tokyo (JP); Hiroyuki RYOSON, Yokohama-shi, Kanagawa (JP)

(73) Assignee: Dexerials Corporation, Shinagawa-ku Tokyo (JP)

(21) Appl. No.: 16/343,838

(22) PCT Filed: Oct. 10, 2017
(86) PCT No.: PCT/JP2017/036618

§ 371 Date: Apr. 22, 2019

(30) Foreign Application Priority Data
Oct. 26, 2016 (JP) 2016-209822

(51) Int. Cl. H05K 7/20; H01L 23/373; H01L 23/00

(52) U.S. Cl. CPC H05K 7/20481; H01L 2224/73253; H01L 24/73; H01L 23/373

(57) ABSTRACT

Provided is a heat conductive sheet having an excellent electromagnetic wave suppressing effect in addition to excellent thermal conductivity. A heat conductive sheet 1 includes a heat conductive sheet body 10 containing a binder resin 11 and fibrous heat conductive fillers 12, and a low permittivity partition member 20 which has a lower dielectric constant than the heat conductive sheet body 10 and separates at least part of the heat conductive sheet body 10.

### TECHNICAL FIELD

The present disclosure relates to a heat conductive sheet, a method of producing a heat conductive sheet, and a semiconductor device which have excellent thermal conductivity and an excellent electromagnetic wave suppressing effect.

### BACKGROUND

In recent years, while there has been a constant trend toward smaller electronic devices, the power consumption of those devices cannot significantly be changed due to the variety of applications used in the devices; therefore, more importance is placed on measures to dissipate heat in the devices.

As measures to dissipate heat in the electronic devices, heat dissipating plates, heat pipes, heat sinks, etc. which are formed using a highly heat conductive metal material such as copper or aluminum are widely used. These heat dissipating components excellent in thermal conductivity are placed to be close to electronic components such as semiconductor packages that are heat generating portions in electronic devices in order to dissipate heat or to reduce temperature variations in the devices. Further, these heat dissipating components excellent in thermal conductivity are placed to extend from electronic components that are heat generating portions to a cool place.

As a heat dissipating component described above, a heat conductive sheet excellent in thermal conductivity is typically used. For example, JP H07-014950 A (PTL 1) discloses a heat dissipating sheet which includes a cured product of a silicone composition containing a heat conductive material and a reinforcing material of a certain type in order to improve flexibility and shape compliance.

However, a heat conductive sheet as described above does not have an electromagnetic noise suppression effect since it is formed from a mixed composition containing a heat conductive filler and a resin. The heat conductive sheet would rather enhance electromagnetic noise depending on the radiation pattern of the electromagnetic noise radiated by a semiconductor. Specifically, due to high permittivity of a heat conductive sheet, the heat conductive sheet gives electromagnetic resonance, and the heat conductive sheet would enhance electromagnetic noise of a plurality of frequencies corresponding to a plurality of resonance modes.

### CITATION LIST

### Patent Literature

PTL 1: JP H07-014950 A

### SUMMARY

### Technical Problem

It could therefore be helpful to provide a heat conductive sheet having an electromagnetic wave suppressing effect in addition to excellent thermal conductivity and a method of producing such a heat conductive sheet.

Further, it could also be helpful to provide a semiconductor device having good heat dissipation properties and an electromagnetic wave suppressing effect using such a heat conductive sheet.

### Solution to Problem

As a result of intensive studies to solve the above problems, we found that separating heat conductive sheet bodies using a material having lower permittivity than the heat conductive sheet bodies can suppress the occurrence of the above-described resonance of electromagnetic noise caused due to high permittivity, which make it possible to effectively suppress electromagnetic noise while achieving good thermal conductivity of the heat conductive sheet.

This disclosure has been made based on these discoveries and primary features thereof are described below.

(1) A heat conductive sheet comprising: a heat conductive sheet body including a binder resin and fibrous heat conductive fillers; and low permittivity partition member that has a lower dielectric constant than the heat conductive sheet body and separates at least part of the heat conductive sheet body.
(2) The heat conductive sheet according to (1) above, wherein the low permittivity partition member completely partitions the heat conductive sheet body.
(3) The heat conductive sheet according to (1) or (2) above, wherein at least two of the low permittivity partition member intersect in the heat conductive sheet body.
(4) The heat conductive sheet according to any one of (1) to (3) above, wherein a dielectric constant of the heat conductive sheet body is 5 or more.
(5) The heat conductive sheet according to any one of (1) to (4) above, wherein a difference between dielectric constants of the heat conductive sheet body and the low permittivity partition member is 2 or more.
(6) The heat conductive sheet according to any one of (1) to (5) above, wherein a partitioning width of the low permittivity partition member is 0.3 mm or more.
(7) The heat conductive sheet according to any one of (1) to (6) above, wherein the fibrous heat conductive filler is carbon fibers.
(8) The heat conductive sheet according to any one of (1) to (7) above, wherein fibrous particles of the fibrous heat conductive filler are oriented in a direction substantially perpendicular to a sheet surface of the heat conductive sheet body.
(9) The heat conductive sheet according to any one of (1) to (8) above, wherein the heat conductive sheet body further includes magnetic metal powder.
(10) The heat conductive sheet according to any one of (1) to (9) above, wherein a surface of the heat conductive sheet body has adhesive property.
(11) A method of producing a heat conductive sheet, comprising the steps of: preparing a sheet base composition containing a binder resin and fibrous heat conductive fillers; orienting fibrous particles of the fibrous heat conductive filler; forming heat conductive sheet bodies by curing the binder resin with the fibrous heat conductive filler being kept oriented; and connecting ends of the plurality of the heat conductive sheet bodies on one plane through a low permittivity partition members having lower permittivity than the heat conductive sheet bodies.
(12) A semiconductor device including a heat source, a heat dissipating member, a heat conductive sheet provided between the heat source and the heat dissipating member, wherein the heat conductive sheet is the heat conductive sheet according to any one of (1) to (10) above.

With the above features, excellent heat dissipation properties and electromagnetic suppression can be achieved.

### Advantageous Effect

This disclosure can provide a heat conductive sheet having an electromagnetic wave suppressing effect in addition to excellent thermal conductivity, and a method of producing the same. Further, a semiconductor device having good heat dissipation properties and an electromagnetic wave suppressing effect can be provided using such a heat conductive sheet.

### BRIEF DESCRIPTION OF THE DRAWINGS

In the accompanying drawings:

FIG. 1A is a perspective view schematically illustrating a heat conductive sheet according to one embodiment of this disclosure, and FIG. 1B is a diagram illustrating a cross section of the heat conductive sheet, taken along line A-A′ of FIG. 1A;

FIGS. 2A and 2B are perspective views each illustrating a heat conductive sheet according to another embodiment of this disclosure;

FIG. 3A is a diagram schematically illustrating a semiconductor device according to one embodiment of this disclosure, and FIG. 3B is a diagram schematically illustrating a semiconductor device according to another embodiment of this disclosure;

FIG. 4 is a diagram illustrating transmission attenuation relative to frequency obtained in Example 1-1 and Comparative Example 1-1;

FIG. 5 is a diagram illustrating transmission attenuation relative to frequency obtained in Example 1-2 and Comparative Example 1-2;

FIG. 6 is a diagram illustrating transmission attenuation relative to frequency obtained in Example 2 and Comparative Example 2;

FIG. 7 is a diagram illustrating transmission attenuations (dB) relative to frequency that vary depending on the width of low permittivity partition members of heat conductive sheets of Samples 3-1;

FIG. 8 is a diagram illustrating transmission attenuations (dB) relative to frequency that vary depending on the permittivity of low permittivity partition members of heat conductive sheets of Samples 3-2; and

FIG. 9 is a diagram illustrating transmission attenuations (dB) relative to frequency that vary depending on the permittivity of low permittivity partition members of heat conductive sheets of Samples 3-3.

### DETAILED DESCRIPTION

Examples of embodiments of this disclosure are described in detail below.

### <Heat Conductive Sheet>

First, a heat conductive sheet of this disclosure is described.

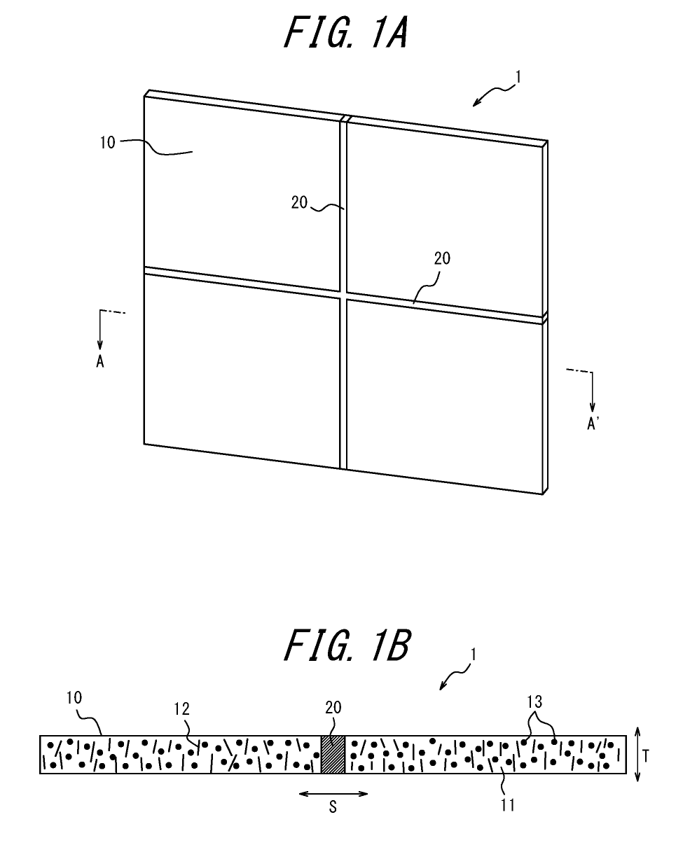

An embodiment of this disclosure is a heat conductive sheet 1 that includes heat conductive sheet bodies 10 containing a binder resin 11 and fibrous heat conductive fillers 12, and low permittivity partition members 20 which separate the heat conductive sheet bodies 10 as illustrated in FIGS. 1A and 1B.

(Binder Resin)

As illustrated in FIG. 1A, the heat conductive sheet 1 of this disclosure includes heat conductive sheet bodies 10.

The binder resin 11 is a resin component serving as a substrate of the heat conductive sheet bodies 10 as illustrated in FIG. 1B The type of the binder resin is not particularly limited and an appropriate known binder resin can be selected.

For example, a thermosetting resin can be given as a binder resin.

Examples of the thermosetting resin include cross-linkable rubbers, epoxy resins, polyimide resins, bismaleimide resins, benzocyclobutene resins, phenolic resins, unsaturated polyesters, diallyl phthalate resins, silicones, polyurethanes, polyimide silicone, thermosetting polyphenylene ethers, and thermosetting modified polyphenylene ethers. One of these resins may be used alone, or two or more of them may be used in combination.

Note that examples of the cross-linkable rubbers include natural rubber, butadiene rubber, isoprene rubber, nitrile rubber, hydrogenated nitrile rubber, chloroprene rubber, ethylene propylene rubber, chlorinated polyethylene, chlorosulfonated polyethylene, butyl rubber, halogenated butyl rubber, fluorocarbon rubber, urethane rubber, acrylic rubber, polyisobutylene rubber, and silicone rubber. One of those may be used alone, or two or more of them may be used in combination.

Of the above thermosetting resins, silicone is preferably used in terms of adhesion and compliance with electronic components, and good formability and weatherability.

The silicone is not particularly limited, and a type of silicone may be appropriately selected depending on the purpose.

In terms of achieving the above formability, weatherability, adhesion, etc., the silicone is preferably a silicone including liquid silicone gel as a base compound and a curing agent. Examples of such a silicone include addition-curable liquid silicone, high-temperature vulcanizing millable silicone using a peroxide for vulcanization, etc. Of these, addition-curable liquid silicone is particularly preferred for a heat dissipating member of an electronic device since adhesion between a heat radiating surface of an electronic component and a heat sink surface is required.

The addition-curable liquid silicone used is preferably a two-part addition-curable silicone, in which polyorganosiloxane having a vinyl group is used as a base compound, and polyorganosiloxane having a Si—H group is used as a curing agent.

For the combination of the liquid silicone gel as the base compound and the curing agent, the combination ratio between the base compound and the curing agent is preferably Base compound:Curing agent=35:65 to 65:35 in a mass ratio.

Further, the content of the binder resin in the heat conductive sheet bodies is not particularly limited and can be appropriately selected depending on the purpose. For example, the content is preferably around 20 vol % to 50 vol %, more preferably 30 vol % to 40 vol % relative to the heat conductive sheet bodies in terms of ensuring formability of the sheets and adhesion with the sheets.

(Heat Conductive Filler)

The heat conductive sheet bodies 10 further include fibrous heat conductive fillers 12 in the binder resin 11 as illustrated in FIG. 1B. The heat conductive filler 12 is a component for improving the thermal conductivity of the sheets. The type of the heat conductive filler is not particularly limited as long as it is fibrous heat conductive fillers, and an appropriate known heat conductive filler can be selected.

Note that “fibrous” of the fibrous heat conductive filler herein means that the fibrous particles of the filler have a shape with a high aspect ratio (approximately 6 or more). Accordingly, in this disclosure, fibrous heat conductive fillers include not only heat conductive fillers having fibrous or stick-like particles but also fillers having particulate particles with a high aspect ratio, heat conductive fillers having flake-like particles, etc.

Here, the kind of the fibrous heat conductive filler is not particularly limited as long as a fibrous and highly heat conductive material is used; for example, a metal such as silver, copper, or aluminum, a ceramic such as alumina, aluminum nitride, silicon carbide, or graphite, or carbon fibers can be used.

Of such fibrous heat conductive fillers, carbon fibers are preferably used in terms of achieving higher thermal conductivity.

For the heat conductive filler, one of those fillers may be used alone, or two or more of them may be used in combination. Further, when two or more heat conductive fillers are used, all of them may be fibrous heat conductive fillers, or the fibrous heat conductive fillers may be used in combination with one or more heat conductive fillers containing particles with a shape other than a fibrous shape.

The kind of the carbon fibers is not particularly limited, and suitable carbon fibers may be selected depending on the purpose. For example, pitch-based carbon fibers, PAN-based carbon fibers, graphitized PBO fibers, and carbon fibers synthesized by arc discharge, laser evaporation, chemical vapor deposition (CVD), catalytic chemical vapor deposition (Cat-CVD), or the like can be used. Of these fibers, graphitized PBO fibers and pitch-based carbon fibers are preferred in terms of achieving high thermal conductivity.

Further, the carbon fibers may be partly or wholly subjected to surface treatment as necessary before use. Examples of the surface treatment include oxidation treatment, nitriding treatment, nitration, sulfonation, or treatments in which a metal, a metal compound, an organic compound, or the like is attached or bonded to a functional group introduced into the surfaces of the carbon fibers by any of these treatments or to the surfaces of the carbon fibers. Examples of the functional group include a hydroxyl group, a carboxyl group, a carbonyl group, a nitro group, and an amino group.

Moreover, the average fiber length (average longitudinal length) of the particles of the fibrous heat conductive filler is not particularly limited either and can be appropriately selected. However, in terms of ensuring high thermal conductivity, the average fiber length is preferably in a range of 50 to 300 μm, more preferably in a range of 75 μm to 275 μm, particularly preferably in a range of 90 μm to 250 μm. When the average fiber length is less than 50 μm, high thermal conductivity would not be obtained, and when the average fiber length is more than 300 μm, dispersibility in the heat conductive sheet decreases, thus sufficient thermal conductivity would not be obtained.

Moreover, the average fiber diameter (average minor axis length) of the fibrous heat conductive filler is not particularly limited either. In terms of ensuring high thermal conductivity, the average fiber diameter is preferably in a range of 4 μm to 20 μm, more preferably in a range of 5 μm to 14 μm.

In terms of ensuring high thermal conductivity, the fibrous heat conductive filler used preferably has an aspect ratio (average longitudinal length/minor axis length) of 6 or more, more preferably 6 to 50. Even when the aspect ratio is lower, thermal conductivity etc. are improved; however, significant improvements in characteristics cannot been achieved for example due to poor fiber orientation. Therefore, the aspect ratio is set to be 6 or more. On the other hand, an aspect ratio exceeding 50 reduces dispersibility in the heat conductive sheet, thus sufficient thermal conductivity would not be achieved.

Here, the average longitudinal length and the average minor axis length of the fibrous heat conductive filler can be calculated as the averages of a plurality of samples calculated from measurements using a microscope, a scanning electron microscope (SEM), etc.

Further, the content of the fibrous heat conductive filler in the heat conductive sheet bodies is not particularly limited and can be appropriately selected depending on the purpose. The content of the fibrous heat conductive filler is preferably 4 vol % to 40 vol %, more preferably 5 vol % to 30 vol %, particularly preferably 6 vol % to 20 vol %. When the content is less than 4 vol %, sufficiently low thermal resistance would hardly be obtained, and a content exceeding 40 vol % would affect the formability of the heat conductive sheet and the fiber orientation of the fibrous heat conductive filler.

Further, in the heat conductive sheet 1 of this disclosure, the particles of the fibrous heat conductive filler 12 are preferably oriented in a direction substantially perpendicular to a sheet surface direction S of the heat conductive sheet bodies 10 (FIG. 1). This makes it possible to achieve excellent thermal conductivity.

Here, the direction substantially perpendicular to the sheet surface is a direction almost the same as a perpendicular direction T to the direction S of the sheet surface. However, when the fibrous heat conductive filler 12 is produced, the orientation of fibers varies to some extent; accordingly, in this specification, a direction deviated from the above perpendicular direction T to the direction S of the sheet surface by ±20° at most can be deemed to be a direction substantially perpendicular to the sheet surface. In terms of achieving higher thermal conductivity, the deviation is from the above direction T perpendicular to the direction S of the sheet is preferably within ±10, more preferably within ±5°.

Note that a method of rectifying the orientation of the fibrous heat conductive filler 12 will be described in detail in the description of a method of producing a heat conductive sheet according to this disclosure. For example, the orientation can be adjusted by forming a sheet base formed product served as a base of the heat conductive sheet body, and adjusting the angle for cutting out the heat conductive sheet body with the particles of the fibrous heat conductive filler being oriented.

(Inorganic Filler)

The heat conductive sheet bodies forming the heat conductive sheet preferably further include an inorganic filler in addition to the above described binder resin and fibrous heat conductive fillers. This can further increase thermal conductivity of the heat conductive sheet and improve strength of the sheet.

The shape, material properties, and average particle diameter of the particles of the inorganic filler are not particularly limited, and an inorganic filler can be appropriately selected depending on the purpose. Examples of the shape include spherical shapes, spheroidal shapes, bulky shapes, particulate shapes, flat shapes, and needle-like shapes. Of these, the spherical shapes and spheroidal shapes are preferred in view of the filling density, and the spherical shapes are particularly preferred.

Examples of materials of the inorganic filler include aluminum nitride (AlN), silica, alumina (aluminum oxide), boron nitride, titania, glass, zinc oxide, silicon carbide, silicon, silicon oxide, aluminum oxide, and metal particles. One of these materials may be used alone, or two or more of them may be used in combination. Of these, alumina, boron nitride, aluminum nitride, zinc oxide, and silica are preferred, and alumina and aluminum nitride are particularly preferred in terms of thermal conductivity.

Further, the inorganic filler used may have been subjected to surface treatment. Treating the inorganic filler with a coupling agent for the surface treatment improves dispersibility of the inorganic filler and improves flexibility of the heat conductive sheet.

The average particle diameter of the inorganic filler can be appropriately selected depending on the kind of the inorganic material.

When the inorganic filler is made of alumina, the average particle diameter is preferably 1 μm to 10 μm, more preferably 1 μm to 5 μm, particularly preferably 4 μm to 5 μm. When the average particle diameter is less than 1 μm, the viscosity would be high and the inorganic filler would hardly be mixed. On the other hand, when the average particle diameter is more than 10 μm, the thermal resistance of the heat conductive sheet would be excessively high.

When the inorganic filler is made of aluminum nitride, the average particle diameter is preferably 0.3 μm to 6.0 μm, more preferably 0.3 μm to 2.0 μm, particularly preferably 0.5 μm to 1.5 μm. When the average particle diameter is less than 0.3 μm, the viscosity would be high and the inorganic filler would be hardly mixed, whereas when the average particle diameter is more than 6.0 μm, the thermal resistance of the heat conductive sheet would be excessively high.

Note that the average partible diameter of the inorganic filler can be measured, for example, using a particle size distribution analyzer, a scanning electron microscope (SEM) and so on.

(Magnetic Metal Powder)

The heat conductive sheet bodies 10 forming the disclosed heat conductive sheet preferably further include magnetic metal powder 13 in addition to the above-described binder resin 11, fibrous heat conductive fillers 12, and inorganic filler (not shown) as illustrated in FIG. 1B. The inclusion of the magnetic metal powder improves the electromagnetic absorption of the heat conductive sheet 1.

The kind of the magnetic metal powder is not particularly limited as long as the powder absorbs electromagnetic radiation, and known magnetic metal powder can be appropriately selected. For example, amorphous metal powder or crystalline metal powder can be used. Examples of amorphous metal powder include Fe—Si—B—Cr-based, Fe—Si—B-based, Co—Si—B-based, Co—Zr-based, Co—Nb-based, and Co—Ta powders, whereas examples of crystalline metal powder include pure iron powder and Fe-based, Co-based, Ni-based, Fe—Ni-based, Fe—Co-based, Fe—Al-based, Fe—Si-based, Fe—Si—Al-based, and Fe—Ni—Si—Al-based powders. Alternatively, as the crystalline metal powder, microcrystalline metal powder obtained by fining crystalline metal powder by adding a slight amount of N (nitrogen), C (carbon), O (oxygen), B (boron), etc. to the crystalline metal powder may be used.

Note that for the magnetic metal powder to be used, two or more magnetic metal powders which are made of different materials or have different average particle diameters may be mixed together.

Further, the particles of the magnetic metal powder are preferably formed into a certain shape, for example, a spherical or flat shape. For example, in order to achieve high filling property, magnetic metal powder having spherical particles with a particle diameter of several micrometers to several tens of micrometers is preferably used. Such magnetic metal powder can be produced by for example atomization or a method of pyrolyzing metal carbonyl. Atomization is a method of forming powder by discharging molten metal, spraying a jet stream of water, inert gas, etc. to the discharged molten metal to form droplets, and solidifying the droplets. Atomization is advantageous in forming spherical powder. When amorphous magnetic metal powder is produced by atomization, the cooling rate is preferably set to approximately 10⁶ (K/s) to prevent molten metal from being crystallized.

When amorphous alloy powder is produced by the above atomization, the surface of the amorphous alloy powder can be made smooth. When amorphous alloy powder having few surface irregularities and a small specific surface area is used as the magnetic metal powder, the filling property of the magnetic metal powder can be made higher in the binder resin. Performing a coupling process on the powder can further improve the filling density.

(Other Components)

Note that the heat conductive sheet bodies forming the heat conductive sheet of this disclosure may contain other components as appropriate depending on the purpose in addition to the above-described binder resin, fibrous heat conductive filler, inorganic filler, and magnetic metal powder.

Examples of the said other components include a thixotropizing agent, a dispersant, a curing accelerator, a retarder, a tackifier, a plasticizer, a flame retardant, an antioxidant, a stabilizer, and a colorant.

(Low Permittivity Partition Member)

The disclosed heat conductive sheet 1 has a lower dielectric constant than the heat conductive sheet bodies 10, and further includes low permittivity partition members 20 which separate at least part of the heat conductive sheet bodies 10 as illustrated in FIG. 1A.

The inclusion of the low permittivity partition members 20 can suppress increase of electromagnetic noise caused due to the permittivity of the heat conductive sheet bodies.

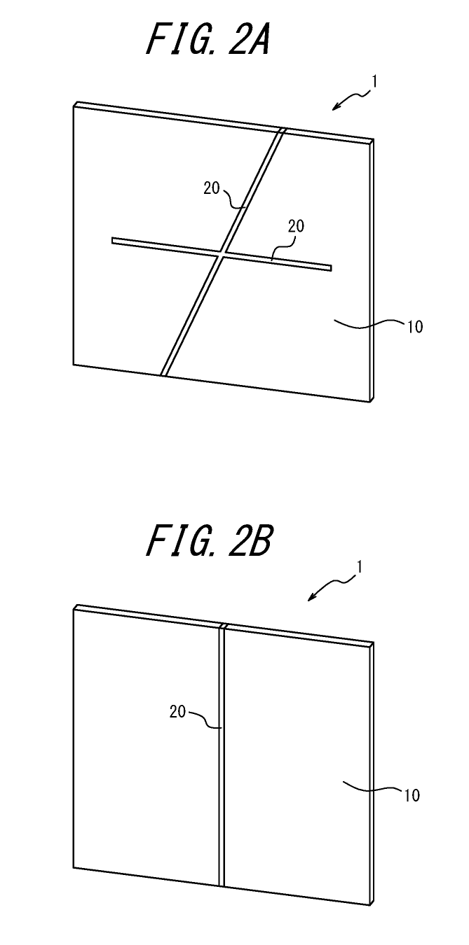

Here, the low permittivity partition members 20 may completely separate the heat conductive sheet bodies 10 as illustrated in FIG. 1A; alternatively, the low permittivity partition members 20 may be arranged to separate part of the heat conductive sheet bodies 10 as illustrated in FIG. 2A. However, in terms of further increasing the electromagnetic wave suppressing effect of the low permittivity partition members 20, the low permittivity partition members 20 preferably completely separate the heat conductive sheet bodies 10 as illustrated in FIG. 1A. Note that in terms of handleability of the disclosed heat conductive sheet, it is preferred that the heat conductive sheet bodies 10 are not completely separated.

The number of the low permittivity partition members is not particularly limited. For example, two low permittivity partition members 20 may be provided as illustrated in FIG. 1A, or one low permittivity partition member 20 may be provided as illustrated in FIG. 2B. Alternatively, although not shown, three or more low permittivity partition members may be provided. However, a higher ratio of low thermal conductivity partition members leads to lower substantial thermal conductivity of the heat conductive sheet, thus the number of partitions may be appropriately selected depending on the balance between the thermal conductivity and the electromagnetic wave suppressing effect.

Further, the arrangement position of the low permittivity partition members in the heat conductive sheet 1 is not particularly limited. For example, two low permittivity partition members 20 may be arranged to intersect as depicted in FIG. 1A and FIG. 2A; alternatively, although not shown, two low permittivity partition members may be arranged in parallel with each other. However, in terms of achieving lower directional dependence of the electromagnetic field that transmits, and achieving an electromagnetic wave suppressing effect of the low permittivity partition members 20, a structure is preferred in which the two low permittivity partition members 20 intersect as illustrated in FIG. 1A and FIG. 2A, and a structure is more preferred in which the low permittivity partition members 20 intersect so that the heat conductive sheet 1 is evenly divided into four parts as illustrated in FIG. 1A.

Note that the kind of the low permittivity partition members is not particularly limited as long as the partition members have a lower dielectric constant than the heat conductive sheet bodies. Preferably, nylon, polyethylene, polyester, glass, etc. can be used, and the air may also be used. The air can be used as the low permittivity partition members by forming grooves in the partition borders between the heat conductive sheet bodies.

Here, the dielectric constant of the heat conductive sheet bodies is preferably 5 or more, more preferably 8 or more. When the dielectric constant of the heat conductive sheet bodies is less than 5, electromagnetic noise does not increase significantly due to the use of the heat conductive sheet; accordingly, there is little necessity to manage the increase and besides a small electromagnetic wave suppressing effect of the low permittivity partition members is expected, thus such heat conductive sheet bodies would not be practical.

In terms of further increasing the electromagnetic wave suppressing effect of the low permittivity partition members, the difference between the dielectric constants of the heat conductive sheet bodies and the low permittivity partition members is preferably 2 or more, more preferably 4 or more.

The partitioning width W of the low permittivity partition members 20 is not particularly limited; however, in terms of achieving a better electromagnetic wave suppressing effect, the partitioning width W is preferably 0.3 mm or more, more preferably 0.5 mm or more. However, when the partitioning width W of the low permittivity partition members 20 is excessively large, the thermal conductivity would be reduced, thus the upper limit of the partitioning width W is preferably approximately 2 mm.

Note that the partitioning width W of the low permittivity partition members 20 is in a direction parallel to a plane of the heat conductive sheet bodies 10 and in a direction perpendicular to the extending direction (longitudinal direction) of the low permittivity partition members 20 as illustrated in FIG. 1A.

Further, the thickness of the low permittivity partition members 20 (the size of the sheet of the heat conductive sheet bodies 10 in the thickness direction T) is not particularly limited and can be appropriately changed depending on the thickness of the heat conductive sheet bodies 10 and design conditions. In terms of obtaining a high electromagnetic wave suppressing effect, however, the low permittivity partition members 20 need to be exposed on at least one side of the heat conductive sheet bodies 10; specifically, the low permittivity partition members preferably have a thickness equal to or more than 90% of the thickness of the heat conductive sheet bodies 10.

Since the disclosed heat conductive sheet 1 is often used while being compressed to improve thermal contact, the thickness of the low permittivity partition members 20 can be set considering the compression amount.

The thickness of the heat conductive sheet bodies 10 is also not particularly limited, and may be appropriately changed depending on for example the place where the sheet is used. The thickness may be in a range of 0.2 mm to 5 mm considering for example the adhesion and the strength of the sheet. The thickness of the entire heat conductive sheet 1 of this disclosure is almost the same as the thickness of the heat conductive sheet bodies 10.

Further, a surface of the heat conductive sheet body preferably has adhesive property. The surface having adhesive property improves the adhesion of the disclosed heat conductive sheet with a heat/electromagnetic radiation source and with a heat dissipating member. This allows the heat conductive sheet to be temporarily attached to the above-mentioned heat/electromagnetic radiation source or to the heat dissipating member, thus displacement therebetween can be effectively prevented in pressure bonding.

Here, the adhesion of the heat conductive sheet body is not particularly limited; however, the 90° peel adhesion (JIS Z 0237: 2009) is preferably 0.1 N/cm in terms of further improving the adhesion with the above heat/electromagnetic radiation source and with the heat dissipating member.

Note that a method of imparting adhesion properties to a surface of the heat conductive sheet body is not particularly limited. For example, adhesion properties may be imparted to the binder resin itself forming the heat conductive sheet bodies, or a highly adhesive tack layer may be formed on the surface of the heat conductive sheet bodies.

<Method of Producing Heat Conductive Sheet>

A method of producing the heat conductive sheet according to this disclosure is described below.

The disclosed method of producing a heat conductive sheet includes the steps of:

preparing a sheet base composition containing a binder resin and fibrous heat conductive fillers (and optionally magnetic metal powder and an inorganic filler, and other components)(sheet base composition preparation step);

orienting the fibrous heat conductive filler relative to a sheet surface (filler orientation step);

forming heat conductive sheet bodies by curing the binder resin with the fibrous heat conductive filler being kept oriented (heat conductive sheet body formation step); and

ends of the plurality of the heat conductive sheet bodies are connected with one or more permittivity partition members having lower permittivity than the heat conductive sheet bodies, on one plane (heat conductive sheet connection step).

Through the above steps, the disclosed heat conductive sheet can be obtained. The obtained heat conductive sheet is excellent in thermal conductivity and the electromagnetic wave suppressing effect as described above.

(Sheet Base Composition Preparation Step)

The disclosed method of producing a heat conductive sheet includes a sheet base composition preparation step.

In this sheet base composition preparation step, the above binder resin, fibrous heat conductive filler, and magnetic metal powder, and an inorganic filler, and/or other components are mixed to prepare a sheet base composition. Note that procedures for mixing and preparing the components are not particularly limited; for example, a sheet base composition is prepared by adding and mixing the fibrous heat conductive filler, inorganic filler, magnetic metal powder, and other components to the binder resin.

(Filler Orientation Step)

The disclosed method of producing a heat conductive sheet includes a filler orientation step.

A method of orienting the fibrous heat conductive filler is not particularly limited as long as the particles of the filler can be oriented in one direction.

As a method of orienting the fibrous heat conductive filler in one direction, for example, the sheet base composition is extruded through or forced into a hollow die under high shear stress. This method allows the fibrous heat conductive filler to be relatively easily oriented, and the fiber orientation of the fibrous heat conductive filler is preferably in a direction substantially perpendicular to the sheet surface (preferably within ±10° from the perpendicular direction).

Specific examples of the method of extruding or forcing the sheet base composition through/into a hollow die under high shear stress include extrusion molding and metal injection molding.

When the sheet base composition is extruded through a die in the extrusion molding, or when a heat conductive resin composition is forced into a mold in the metal injection molding, the binder resin flows when the heat conductive resin composition is forced into the mold, and the carbon fibers are oriented in the flowing direction. On this occasion, if a slit is provided at the tip of the die, the carbon fibers are more easily oriented.

The size and the shape of a formed product (block formed product) can be determined depending on the desired size of the heat conductive sheet. For example, the shape may be a cuboid in which a cross section has a longitudinal size of 0.5 cm to 15 cm and a lateral size of 0.5 cm to 15 cm. The length of the cuboid may be determined as needed.

(Heat Conductive Sheet Body Formation Step)

The disclosed method of producing a heat conductive sheet includes a heat conductive sheet body formation step.

Here, a heat conductive sheet body is a cutout from a sheet base formed product serving as a base of the heat conductive sheet body. The sheet base formed product is formed by curing the binder resin while maintaining the orientation of the fibrous heat conductive filler, achieved in the above filler orientation step.

The method and conditions for curing the binder resin may be changed depending on the kind of the binder resin. For example, when the binder resin is a thermosetting resin, the curing temperature at which heat curing is performed can be adjusted. When the thermosetting resin contains liquid silicone gel as a base compound and a curing agent, curing is preferably performed at a curing temperature of 80° C. to 120° C. Further, the curing time for heat curing can be, but not limited to, 1 hour to 10 hours.

(Heat Conductive Sheet Connection Step)

The disclosed method of producing a heat conductive sheet includes a heat conductive sheet connection step.

In the heat conductive sheet connection step, a plurality of the heat conductive sheet bodies obtained through the above steps are prepared, and the heat conductive sheet bodies are connected on one plane through a low permittivity partition members having lower permittivity than the heat conductive sheet bodies previously prepared.

Connecting ends of the heat conductive sheet bodies with the low permittivity partition member therebetween allows a resultant one heat conductive sheet to have a structure in which the low permittivity partition member at least partly separates the heat conductive sheet bodies.

Conditions for connecting the heat conductive sheet bodies and the low permittivity partition member are not particularly limited. For example, the connection may be performed by pressing the plurality of heat conductive sheet bodies with the low permittivity partition member being sandwiched between their ends using a hand roller or the like.

Further, the connection operation may be performed simultaneously in a pressing step to be described.

In the heat conductive sheet connection step, the heat conductive sheet bodies are connected with the low permittivity partition member therebetween on one plane; however, when the air is used as the low permittivity partition member, the heat conductive sheet of this disclosure may be formed by forming a groove in one heat conductive sheet body without performing the connection between the heat conductive sheet bodies with the low permittivity partition member therebetween.

(Pressing Step)

The disclosed method of producing a heat conductive sheet may optionally include a step of pressing the heat conductive sheet to smooth the surfaces of the heat conductive sheet, increase the adhesion, and reduce the interface contact resistance when a light load is applied (pressing step).

The pressing can be performed for example using a pair of pressing units each including a plate and a press head having a flat surface. Alternatively, pressing may be performed using pinch rolls.

The pressure applied by the pressing is not particularly limited and may be appropriately selected depending on the purpose; however, since an excessively low pressure would not change the thermal resistance from before pressing and an excessively high pressure extends the sheet, the pressure is preferably in a range of 0.1 MPa to 100 MPa, more preferably 0.5 MPa to 95 MPa.

Whichever of the above heat conductive sheet connection step and the pressing step may be performed first. Accordingly, the heat conductive sheet bodies can be connected with the low permittivity partition member therebetween after performing the pressing step to obtain the thin film heat conductive sheet bodies.

<Semiconductor Device>

A semiconductor device of this disclosure is described below.

A semiconductor device of this disclosure includes a heat source, a heat dissipating member, and a heat conductive sheet sandwiched between the heat source and the heat dissipating member, and the heat conductive sheet is the heat conductive sheet of this disclosure described above.

With the use of the disclosed heat conductive sheet, the obtained semiconductor device has good heat dissipation properties and has an excellent electromagnetic wave suppressing effect.

Here, the heat source is not particularly limited as long as it generates heat in the semiconductor device. For example, the heat source may be an electronic component, and examples of the electronic component include a CPU, an MPU, a graphic processing unit, and an image sensor.

Further, the heat dissipating member conducts heat generated from the heat source and dissipates the heat to the outside. Examples of the dissipating member include a radiator, a cooler, a heat sink, a heat spreader, a die pad, a printed circuit board, a cooling fan, a Peltier device, a heat pipe, a metal cover, and a chassis.

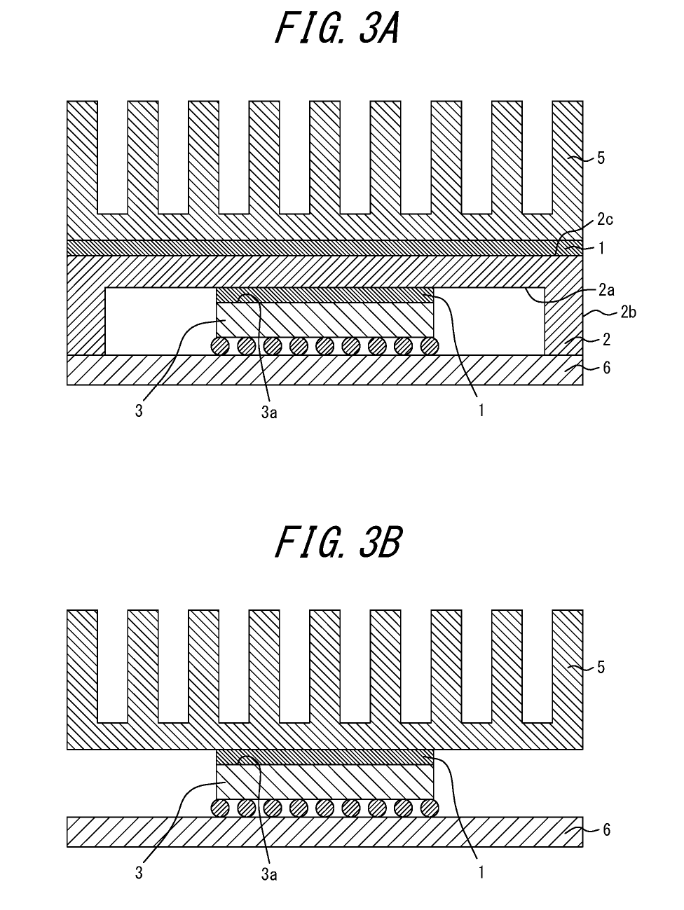

An example of the disclosed semiconductor device is described with reference to FIGS. 3A and 3B.

FIG. 3A is a schematic cross-sectional view illustrating an example of the disclosed semiconductor device. The semiconductor device includes a heat conductive sheet 1, a heat spreader 2, an electronic component 3, a heat sink 5, and a wiring board 6.

The heat conductive sheet 1 absorbs unnecessary electromagnetic waves generated by the electronic component 3 and electromagnetic radiation from the other components, and dissipates heat generated by the electronic component 3. As illustrated in FIG. 3A, the heat conductive sheet 1 is fixed to a main surface 2a of the heat spreader 2 facing the electronic component 3 and is sandwiched between the electronic component 3 and the heat spreader 2. Further, the heat conductive sheet 1 is sandwiched between the heat spreader 2 and the heat sink 5.

The heat spreader 2 is for example formed into a square sheet shape, and has the main surface 2a facing the electronic component 3 and side walls 2b provided to stand along the circumference of the main surface 2a. For the heat spreader 2, the heat conductive sheet 1 is provided on the main surface 2a surrounded by the side walls 2b, and the heat sink 5 is provided on another surface 2c opposite to the main surface 2a (opposite surface 2c) with the heat conductive sheet 1 therebetween. When the heat spreader 2 has higher thermal conductivity, the heat spreader 2 has lower thermal resistance and effectively absorbs heat of the electronic component 3 such as a semiconductor device. Accordingly, the heat spreader 2 can be formed using for example copper or aluminum with high thermal conductivity.

The electronic component 3 is for example a semiconductor package such as a BGA, and is mounted on the wiring board 6. Further, also for the heat spreader 2, end surfaces of the side walls 2b are attached to the wiring board 6, thus the side walls 2b surround the electronic component 3 spaced by a given distance.

Moreover, the heat conductive sheet 1 is attached to the main surface 2a of the heat spreader 2, so that the heat conductive sheet 1 absorbs heat generated from the electronic component 3 and the heat is dissipated by the heat sink 5. The heat spreader 2 and the heat conductive sheet 1 can be attached together by the adhesiveness of the heat conductive sheet 1 itself.

FIG. 3B is a schematic cross-sectional view illustrating another example of the disclosed semiconductor device.

The semiconductor device includes a heat conductive sheet 1, a heat spreader 2, an electronic component 3, a heat sink 5, and a wiring board 6.

The heat conductive sheet 1 absorbs unnecessary electromagnetic waves generated by the electronic component 3 and electromagnetic radiation from the other components, and dissipates heat generated by the electronic component 3. As illustrated in FIG. 3B, the heat conductive sheet 1 is fixed to a top surface 3a of the electronic component 3 and is sandwiched between the electronic component 3 and the heat sink 5.

### EXAMPLES

Next, this disclosure will be described in detail based on examples. However, this disclosure is not limited to the following examples in any way.

### Example 1

In Example 1, models of heat conductive sheets used for analysis using a 3D electromagnetic field simulator (Examples 1-1 to 1-2, and Comparative Examples 1-1 to 1-2) were prepared. Specific conditions for the models of the heat conductive sheets are described below.

### (1) Example 1-1

A length 30 mm×width 30 mm×thickness 1 mm heat conductive sheet including heat conductive sheet bodies with a dielectric constant of 15 and low permittivity partition members with a dielectric constant of 3.2. The low permittivity partition members had a thickness of 1 mm and a partitioning width of 0.5 mm and had a cross shape in which the members intersected at the center as illustrated in FIG. 1A.

### Comparative Example 1-1

A length 30 mm×width 30 mm×thickness 1 mm heat conductive sheet including a heat conductive sheet body having a dielectric constant of 15. Note that this heat conductive sheet included no low permittivity partition member.

### (2) Example 1-2

A length 30 mm×width 30 mm×thickness 1 mm heat conductive sheet including heat conductive sheet bodies with a dielectric constant of 30 and low permittivity partition members with a dielectric constant of 3.2. The low permittivity partition members had a thickness of 1 mm and a partitioning width of 0.5 mm and had a cross shape in which the members intersected at the center as illustrated in FIG. 1A.

### Comparative Example 1-2

A length 30 mm×width 30 mm×thickness 1 mm heat conductive sheet including a heat conductive sheet body having a dielectric constant of 30. Note that this heat conductive sheet included no low permittivity partition member.

The low permittivity partition members having a dielectric constant of 3.2 used in each example was assumed to be formed of a low permittivity material such as nylon 66 (dielectric constant: 3.16 to 3.75). Further, the thermal conductivity of the models of the prepared heat conductive sheets is estimated to have been approximately 1.5 W/mK.

Transmission Attenuation Analysis

The transmission attenuation (dB) of each sample was determined by analysis following the inter-decoupling measurement according to IEC 62333-2. Specifically, a feeding probe and a receiving probe were modeled using a 3D electromagnetic field simulator HFSS (provided by ANSYS Inc.), a pair of loop antennas were arranged, a heat conductive sheet was placed as a test sample between the antennas, and the transmission characteristics S21 from one of the antennas to the other were evaluated and compared. The transmission attenuation was expressed as a value obtained by subtracting S21r (insertion loss of the case where the test sample was not used) from S21m (insertion loss of the case where the test sample was used), the distance between the antennas was 6 mm, and the sample size was 30 mm×30 mm×1 mm.

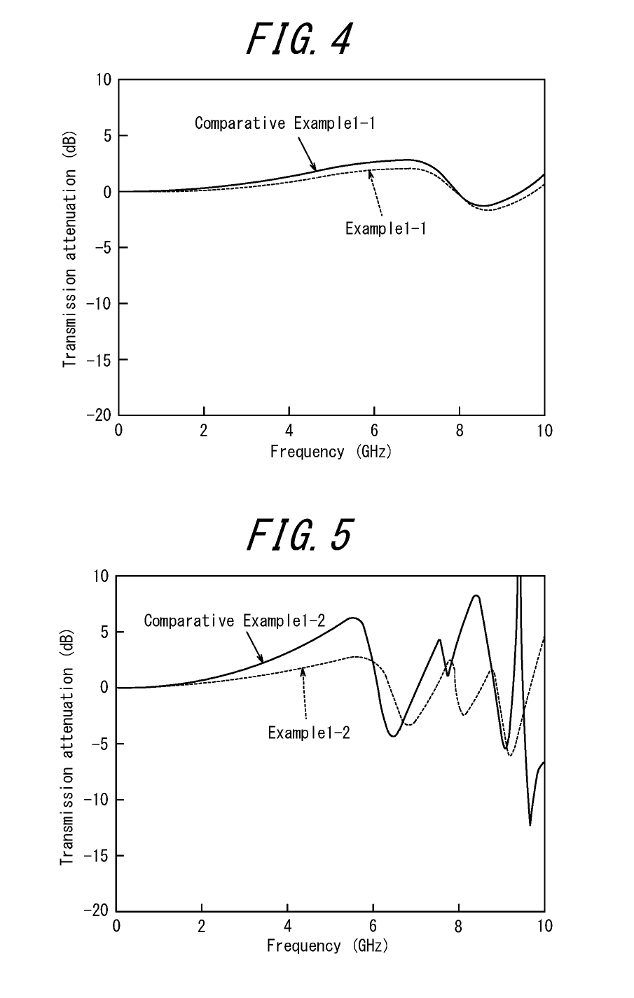

FIG. 4 depicts the transmission attenuation (dB) relative to frequency in Example 1-1 and Comparative Example 1-1, whereas the FIG. 5 depicts the transmission attenuation (dB) relative to frequency in Example 1-2 and Comparative Example 1-2.

From the results in FIG. 4 and FIG. 5, undulations indicating fluctuations in the signal strength relative to the frequency are found in both Comparative Example 1-1 and Comparative Example 1-2 although the undulations are the most remarkable in Comparative Example 1-2 of a high dielectric constant. On the other hand, in both Example 1-1 and Example 1-2, smaller undulations are found, which means that enhancement of electromagnetic signals was suppressed.

Thus, although depending on the size and the thickness of the heat conductive sheets, an electromagnetic wave suppressing effect was found to be obtained in Example 1-1 and Example 1-2, and the effect was found to be more significant in Example 1-2 using the heat conductive sheet having a high dielectric constant.

### Example 2

In Example 2, samples of heat conductive sheets (Example 2, Comparative Example 2) were actually prepared under the following conditions.

A two-part addition-curable liquid silicone was used as a resin binder, alumina powder having an average particle diameter of 5 μm was used as an inorganic filler, pitch-based carbon fibers having an average fiber length of 200 μm (“heat conductive fiber” manufactured by Nippon Graphite Fiber Co.) was used as fibrous heat conductive fillers, and these materials were mixed in a dispersed manner such that a volume ratio of Two-part addition-curable liquid silicone:Alumina powder:Pitch-based carbon fibers=35 vol %:53 vol %:12 vol % was achieved, thus a silicone composition (sheet base composition) was prepared.

The two-part addition-curable liquid silicone had been obtained by mixing part A silicone (base compound) and part B silicone (curing agent) at a ratio of 19:16. The resultant silicone composition was extruded through a cuboidal 30 mm×30 mm die in which a release coated PET film was pasted to the inner walls, thus a silicone formed product was formed. The resultant silicone formed product was cured in an oven at 100° C. for 6 hours to obtain a silicone cured product.

Next, the resultant silicone cured product was cut with an ultrasonic cutter in a direction perpendicular to the longitudinal direction of oriented carbon fibers, and the cut surface was used as a sheet surface, thus a sample of a 1 mm thick heat conductive sheet body in which the carbon fibers are oriented in a direction substantially perpendicular to the sheet surface was obtained. The slicing speed for the ultrasonic cutter was 50 mm per second. Further, the ultrasonic vibration applied to the ultrasonic cutter had a vibration frequency of 20.5 kHz and an amplitude of 60 μm.

The resultant heat conductive sheet body was pasted on a PET film, and grooves with a width of 0.5 mm were then provided in a cross shape as illustrated in FIG. 1A and had low permittivity partition members of air were formed, thus a heat conductive sheet was prepared as a sample.

Note that in Comparative Example 2, the above-described low permittivity partition members were not formed, and the resultant heat conductive sheet body was used as a sample.

Transmission Attenuation Measurement

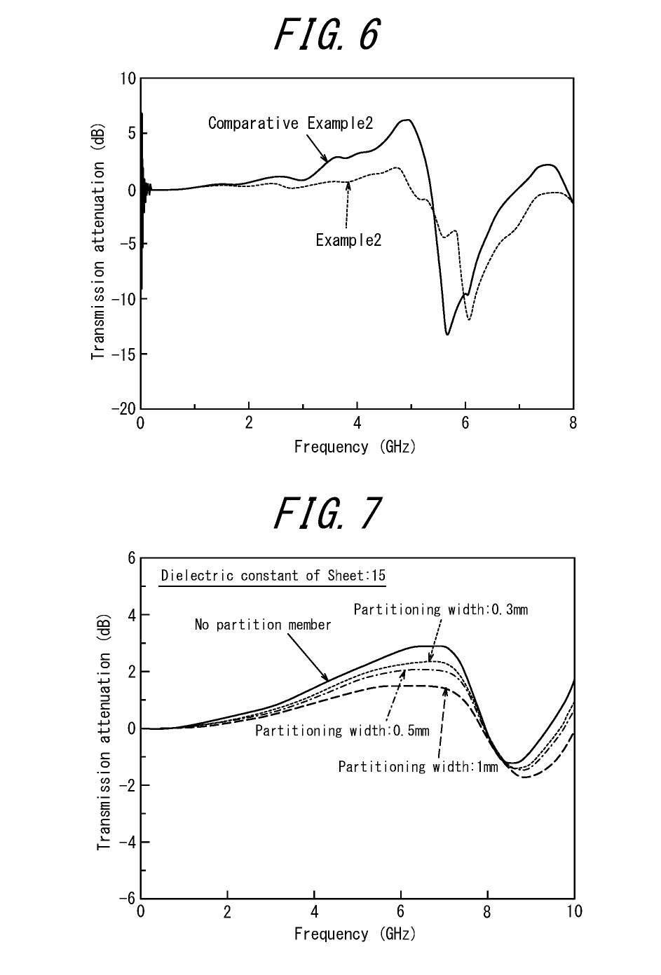

The transmission attenuation was measured by inter-decoupling measurement according to IEC 62333-2. FIG. 6 depicts the transmission attenuation (dB) relative to frequency in Example 2 and Comparative Example 2.

FIG. 6 illustrates results in which smaller undulations were found in the transmission attenuation characteristics and enhancement of electromagnetic noise was suppressed in the sample of Example 2 including a low permittivity partition member in the heat conductive sheet as with the results obtained from FIG. 4 and FIG. 5.

### Example 3

In Example 3, the transmission attenuation was analyzed using a 3D electromagnetic field simulator. Specific conditions for models of heat conductive sheets are described below.

(1) Samples 3-1: Length 30 mm×width 30 mm×thickness 1 mm heat conductive sheets including heat conductive sheet bodies with a dielectric constant of 15 and low permittivity partition members. The low permittivity partition members had a thickness of 1 mm and a varied partitioning width of 0 mm (no partition member), 0.3 mm, 0.5 mm, and 1 mm and had a cross shape in which the members intersected at the center as illustrated in FIG. 1A.
(2) Samples 3-2: Length 30 mm×width 30 mm×thickness 1 mm heat conductive sheets including heat conductive sheet bodies with a dielectric constant of 15 and low permittivity partition members with a dielectric constant of 3.2. The low permittivity partition members had a thickness of 1 mm, a partitioning width of 1 mm, and a varied dielectric constant of 1, 3.2, and 5, and had a cross shape in which the members intersected at the center as illustrated in FIG. 1A.
(3) Samples 3-3: Length 30 mm×width 30 mm×thickness 1 mm heat conductive sheets including heat conductive sheet bodies with a dielectric constant of 5 and low permittivity partition members with a dielectric constant of 3.2. The low permittivity partition members had a thickness of 1 mm, a partitioning width of 1 mm, and a varied dielectric constant of 1 and 3.2, and had a cross shape in which the members intersected at the center as illustrated in FIG. 1A.

Transmission Attenuation Analysis

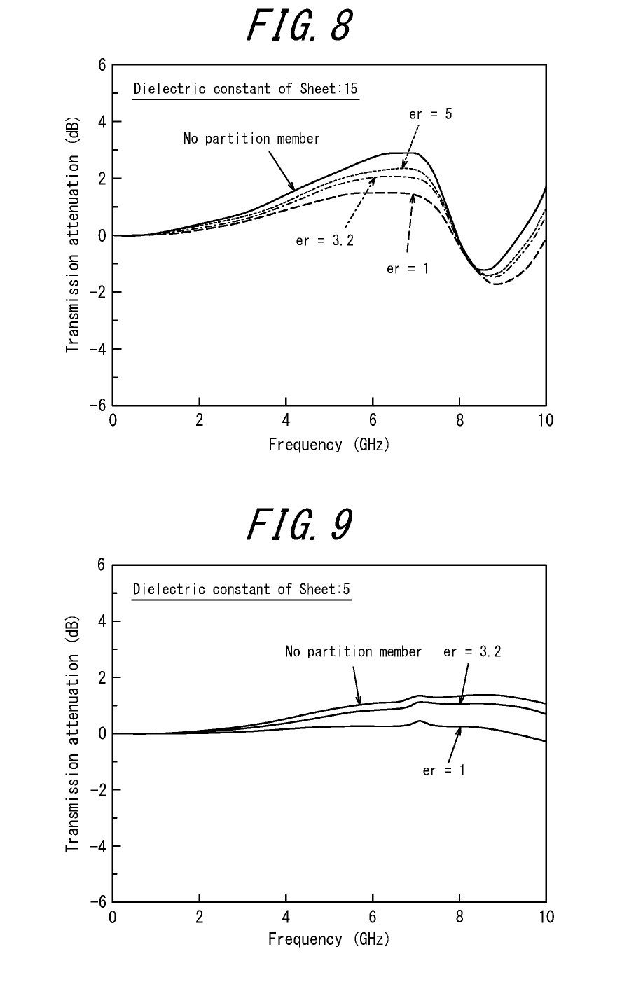

The transmission attenuation of each sample was obtained by the same method as in Example 1-1 (analysis following the inter-decoupling measurement according to IEC 62333-2). FIG. 7 depicts the transmission attenuation (dB) relative to frequency for Samples 3-1, the FIG. 8 depicts the transmission attenuation (dB) relative to frequency for Samples 3-2, and FIG. 9 depicts the transmission attenuation (dB) relative to frequency for Samples 3-3.

The results in FIG. 7 demonstrate that although a larger groove width of the low permittivity partition members suppressed undulations in the transmission attenuation more, even a small width of approximately 0.3 mm had an effect.

Further, the results in FIG. 8 demonstrate that a larger difference between the dielectric constants of the heat conductive sheet bodies and the low permittivity partition members results in a better electromagnetic noise suppression effect.

Further, the results in FIG. 9 demonstrate that the electromagnetic noise suppression effect was observed even when the difference between the dielectric constants of the heat conductive sheet bodies and the low permittivity partition members was as small as approximately 1.8.

### INDUSTRIAL APPLICABILITY

This disclosure can provide a heat conductive sheet having an excellent electromagnetic wave suppressing effect in addition to excellent thermal conductivity, and a method of producing the same. Further, a semiconductor device having good heat dissipation properties and an electromagnetic wave suppressing effect can be provided using the heat conductive sheet.

### REFERENCE SIGNS LIST

1 Heat conductive sheet
2 Heat spreader
2a Main surface
2b Side wall
2c Opposite surface
3 Electronic component
3a Top surface
5 Heat sink
6 Wiring board
10 Heat conductive sheet body
11 Binder resin
12 Fibrous heat conductive filler
13 Magnetic metal powder
20 Low permittivity partition member
S Sheet surface direction
T Direction perpendicular to sheet surface

1. (canceled)

2. A heat conductive sheet comprising:
a heat conductive sheet body including a binder resin and fibrous heat conductive fillers; and
low permittivity partition member that has a lower dielectric constant than the heat conductive sheet body and separates at least part of the heat conductive sheet body,
wherein the low permittivity partition member completely partitions the heat conductive sheet body.

3. A heat conductive sheet comprising:
a heat conductive sheet body including a binder resin and fibrous heat conductive fillers; and
low permittivity partition member that has a lower dielectric constant than the heat conductive sheet body and separates at least part of the heat conductive sheet body,
wherein at least two of the low permittivity partition member intersect in the heat conductive sheet body.

4. The heat conductive sheet according to claim 2, wherein a dielectric constant of the heat conductive sheet body is 5 or more.

5. The heat conductive sheet according to claim 2, wherein a difference between dielectric constants of the heat conductive sheet body and the low permittivity partition member is 2 or more.

6. The heat conductive sheet according to claim 2, wherein a partitioning width of the low permittivity partition member is 0.3 mm or more.

7. The heat conductive sheet according to claim 2, wherein the fibrous heat conductive filler is carbon fibers.

8. The heat conductive sheet according to claim 2, wherein fibrous particles of the fibrous heat conductive filler are oriented in a direction substantially perpendicular to a sheet surface of the heat conductive sheet body.

9. The heat conductive sheet according to claim 2, wherein the heat conductive sheet body further includes magnetic metal powder.

10. The heat conductive sheet according to claim 2, wherein a surface of the heat conductive sheet body has adhesive property.

11. A method of producing a heat conductive sheet, comprising the steps of:
preparing a sheet base composition containing a binder resin and fibrous heat conductive fillers;
orienting fibrous particles of the fibrous heat conductive filler;
forming heat conductive sheet bodies by curing the binder resin with the fibrous heat conductive filler being kept oriented; and
connecting ends of the plurality of the heat conductive sheet bodies on one plane through a low permittivity partition members having lower permittivity than the heat conductive sheet bodies.

12. A semiconductor device including a heat source, a heat dissipating member, a heat conductive sheet provided between the heat source and the heat dissipating member,
wherein the heat conductive sheet is the heat conductive sheet according to claim 2.

13. The heat conductive sheet according to claim 3, wherein a dielectric constant of the heat conductive sheet body is 5 or more.

14. The heat conductive sheet according to claim 3, wherein a difference between dielectric constants of the heat conductive sheet body and the low permittivity partition member is 2 or more.

15. The heat conductive sheet according to claim 3, wherein a partitioning width of the low permittivity partition member is 0.3 mm or more.

16. The heat conductive sheet according to claim 3, wherein the fibrous heat conductive filler is carbon fibers.

17. The heat conductive sheet according to claim 3, wherein fibrous particles of the fibrous heat conductive filler are oriented in a direction substantially perpendicular to a sheet surface of the heat conductive sheet body.

18. The heat conductive sheet according to claim 3, wherein the heat conductive sheet body further includes magnetic metal powder.

19. The heat conductive sheet according to claim 3, wherein a surface of the heat conductive sheet body has adhesive property.

20. A semiconductor device including a heat source, a heat dissipating member, a heat conductive sheet provided between the heat source and the heat dissipating member,
wherein the heat conductive sheet is the heat conductive sheet according to claim 3.
